(19) United States
(12) Patent Application Publication
(10) Pub. No.: US 2025/0329565 A1
(43) Pub. Date: Oct. 23, 2025

(54) ELECTROSTATIC CHUCK MEMBER, ELECTROSTATIC CHUCK DEVICE, AND METHOD FOR MANUFACTURING ELECTROSTATIC CHUCK MEMBER

(71) Applicant: SUMITOMO OSAKA CEMENT CO., LTD., Tokyo (JP)

(72) Inventors: Taku ICHIYOSHI, Tokyo (JP); Satoyoshi INUI, Tokyo (JP); Takeshi OTSUKA, Tokyo (JP)

(73) Assignee: SUMITOMO OSAKA CEMENT CO., LTD., Tokyo (JP)

(21) Appl. No.: 18/721,105

(22) PCT Filed: Dec. 9, 2022
(86) PCT No.: PCT/JP2022/045535

§ 371 Date: Nov. 22, 2024

(30) Foreign Application Priority Data
Dec. 24, 2021 (JP) 2021-210715

(51) Int. Cl. H01L 21/683; H01J 37/32

(52) U.S. Cl. CPC H01L 21/6833; H01J 37/32715; H01J 2237/2007

(57) ABSTRACT

Provided is an electrostatic chuck member including: a dielectric substrate having a placement surface on which a sample is mounted, wherein a direction orthogonal to the placement surface is a thickness direction thereof; and an adsorption electrode which is embedded in the dielectric substrate, in which a gas flow path which extends along a planar direction of the placement surface, is provided in the dielectric substrate, the gas flow path has an inner surface which includes a bottom surface portion that faces the same direction as the placement surface, a top surface portion that faces the bottom surface portion, and a pair of side surface portions that connect the bottom surface portion and the top surface portion, wherein at least one of the side surface portions is inclined with respect to the thickness direction.

### TECHNICAL FIELD

The present invention relates to an electrostatic chuck member, an electrostatic chuck device, and a method for manufacturing the electrostatic chuck member.

This application claims priority based on Japanese Patent Application No. 2021-210715 filed on Dec. 24, 2021, the content of which is incorporated herein by reference.

### BACKGROUND ART

In a semiconductor manufacturing process, an electrostatic chuck device that holds a semiconductor wafer in a vacuum environment is used. In the electrostatic chuck device, a plate-shaped sample such as a semiconductor wafer is placed on a placement surface, and an electrostatic force is generated between the plate-shaped sample and an internal electrode to adsorb and fix the plate-shaped sample. Patent Literature No. 1 discloses an electrostatic adsorption device including a circulation space having an arc shape in a plan view through which gas flows into an insulator formed of a ceramic.

### CITATION LIST

### Patent Literature

[Patent Literature No. 1] Japanese Patent No. 3357991

### SUMMARY OF INVENTION

### Technical Problem

By providing a gas flow path in the electrostatic chuck member, the electrostatic chuck member can be cooled by heat transfer gas. However, in an electrostatic chuck member in the related art, a steep temperature gradient is generated at a boundary between a region in which the gas flow path is provided and a region in which the gas flow path is not provided. As a result, there is a problem in that a temperature distribution of a wafer mounted on a placement surface is likely to be non-uniform.

An object of the present invention is to provide an electrostatic chuck member where a temperature distribution of a wafer is likely to be uniform, an electrostatic chuck device, and a method for manufacturing an electrostatic chuck member.

### Solution to Problem

A first aspect of the present invention provides the following electrostatic chuck member.

The electrostatic chuck member according to the first aspect of the present invention includes: a dielectric substrate having a placement surface on which a sample is mounted, wherein a direction orthogonal to the placement surface is a thickness direction thereof; and an adsorption electrode which is embedded in the dielectric substrate, in which a gas flow path, which extends along a planar direction of the placement surface, is provided in the dielectric substrate, the gas flow path has an inner surface which includes a bottom surface portion that faces the same direction as the placement surface, a top surface portion that faces the bottom surface portion, and a pair of side surface portions that connect the bottom surface portion and the top surface portion, wherein at least one of the pair of side surface portions is inclined with respect to the thickness direction.

The sample refers to a substance that can be mounted on the placement surface of the electrostatic chuck device and can be electrostatically chucked. The sample may be a wafer, a plate-shaped sample, or a plate.

It is preferable that the first aspect of the present invention has the following characteristics. It is also preferable to combine two or more of these characteristics. In the above-described electrostatic chuck member, the gas flow path may extend in an arc shape with respect to a center of the dielectric substrate.

In the above-described electrostatic chuck member, among the pair of side surface portions, one side surface portion may be an inner peripheral side surface portion which is disposed on an arc inner peripheral side and the other side surface portion may be an outer peripheral side surface portion which is disposed on an arc outer peripheral side, and an inclination angle of the outer peripheral side surface portion may be larger than an inclination angle of the inner peripheral side surface portion.

In the above-described electrostatic chuck member, a plurality of the gas flow paths may include an inner peripheral flow path which extends in an arc shape with respect to a center of the dielectric substrate, and an outer peripheral flow path which extends in an arc shape and is concentrically disposed outside of the inner peripheral flow path, wherein among the pair of side surface portions thereof, one side surface portion may be an inner peripheral side surface portion which is disposed on an arc inner peripheral side and the other side surface portion may be an outer peripheral side surface portion which is disposed on an arc outer peripheral side, and an inclination angle of the outer peripheral side surface portion of the outer peripheral flow path may be larger 10 than an inclination angle of the outer peripheral side surface portion of the inner peripheral flow path.

In the above-described electrostatic chuck member, an inclination angle of the inner peripheral side surface portion of the outer peripheral flow path may be larger than an inclination angle of the inner peripheral side surface portion of the inner peripheral flow path.

In the above-described electrostatic chuck member, the dielectric substrate may include a first supporting plate and a second supporting plate which are stacked in the thickness direction, and the gas flow path may be provided between the first supporting plate and the second supporting plate.

In the above-described electrostatic chuck member, the first supporting plate and the second supporting plate may be joined to each other through a joining layer, at least a part of the side surface portion may be located in the joining layer, and a thermal conductivity of the joining layer may be higher than thermal conductivities of the first supporting plate and the second supporting plate.

The above-described electrostatic chuck member may further include a sub-electrode layer that is embedded in the dielectric substrate, in which the sub-electrode layer may be disposed on the same plane as the gas flow path.

A second aspect of the present invention provides the following electrostatic chuck device.

The electrostatic chuck device according to the aspect of the present invention includes: the above-described electrostatic chuck member; and a base that supports the electrostatic chuck member from a side opposite to the placement surface.

A third aspect of the present invention provides the following method for manufacturing an electrostatic chuck member.

The method for manufacturing an electrostatic chuck member according to the third aspect of the present invention is a method for manufacturing an electrostatic chuck member which includes a dielectric substrate, which includes a first supporting plate and a second supporting plate, and an adsorption electrode embedded in the dielectric substrate, the method including: a recessed groove forming step of forming a recessed groove on at least one of the first supporting plate and the second supporting plate; and a joining step of stacking and joining the first supporting plate and the second supporting plate in a thickness direction thereof, in which in the recessed groove forming step, the recessed groove is formed wherein a width dimension thereof increases toward an opening side thereof.

It is preferable that the third aspect of the present invention has the following characteristics. It is also preferable to combine two or more of these characteristics. In the above-described method for manufacturing an electrostatic chuck member, in the joining step, a surface of the supporting plate where the recessed groove has been formed may be joined to a surface of the other supporting plate, the recessed groove may have an arc shape in a plan view, the recessed groove may include an inner peripheral side surface portion which is disposed on an arc inner peripheral side, an outer peripheral side surface portion which is disposed on an arc outer peripheral side, and a bottom surface portion which connects the side surface portions, and at least one of the side surface portions may be inclined with respect to the thickness direction of the supporting plate.

In the above-described method for manufacturing an electrostatic chuck member, an inclination angle of the outer peripheral side surface portion may be larger than an inclination angle of the inner peripheral side surface portion.

The above-described method for manufacturing an electrostatic chuck member may further include an application step which is performed between the recessed groove forming step and the joining step, wherein a joining layer paste is applied to at least one of the surface of the supporting plate, where the recessed groove is provided, and the surface of the other supporting plate, and the first supporting plate and the second supporting plate may be joined through the joining layer paste.

### Advantageous Effects of Invention

According to one aspect of the present invention, it is possible to provide an electrostatic chuck member where a temperature distribution of a wafer is likely to be uniform, an electrostatic chuck device, and a method for manufacturing an electrostatic chuck member.

### BRIEF DESCRIPTION OF DRAWINGS

FIG. 1 is a schematic cross-sectional view illustrating an example of an electrostatic chuck device according to one embodiment of the present invention.

FIG. 2 is a schematic plan view illustrating the electrostatic chuck member according to the embodiment of the present invention.

FIG. 3 is an enlarged view illustrating a region III of FIG. 1.

FIG. 4 is a schematic view illustrating a recessed groove forming step in a method for manufacturing the electrostatic chuck member according to the embodiment of the present invention.

FIG. 5 is a schematic view illustrating an example of an application step in the method for manufacturing the electrostatic chuck member according to the embodiment of the present invention.

FIG. 6 is a schematic view illustrating an example of a joining step in the method for manufacturing the electrostatic chuck member according to the embodiment of the present invention.

FIG. 7 is a partial schematic cross-sectional view illustrating an electrostatic chuck member according to a modification example of the present invention.

### DESCRIPTION OF EMBODIMENTS

A preferable example of each of embodiments of an electrostatic chuck device according to the present invention will be described below with reference to the drawings. In all of the following drawings, dimensions, ratios, and the like of respective components may be appropriately different from the actual ones in order to easily understand the drawings. In addition, the following description is made for better understanding of the scope of the invention, and does not limit the present invention unless otherwise specified. Within a range not departing from the present invention, changes, omissions, or additions can be made for a number, an amount, a position, a size, a numerical value, a ratio, an order, a kind, a shape, or the like.

In addition, each of the drawings illustrates a Z-axis. In the present specification, the Z-axis is a direction orthogonal to a placement surface as necessary. In addition, an upper surface that is a direction in which the placement surface faces is defined as a +Z direction.

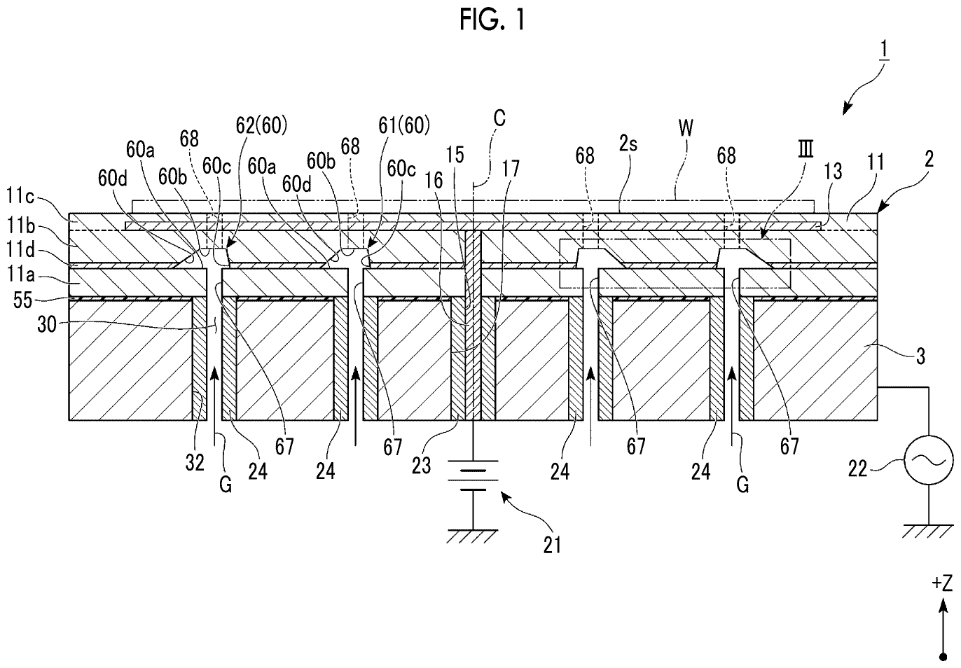

FIG. 1 is a schematic cross-sectional view showing an electrostatic chuck device 1 according to the present embodiment.

The electrostatic chuck device 1 includes: an electrostatic chuck member 2 having a placement surface 2s on which a wafer (sample) W is mounted includes: a base 3 that supports the electrostatic chuck member 2 from a side opposite to the placement surface 2s; and a feeding terminal 16 that applies a voltage to the electrostatic chuck member 2. A focus ring surrounding the wafer W may be disposed on an outer peripheral portion of an upper surface of the electrostatic chuck member 2. Any shape, any size, or any material of the wafer W can be selected. For example, the wafer W is preferably a circular plate.

The electrostatic chuck member 2 has a disk shape around a central axis C. The electrostatic chuck member 2 includes a dielectric substrate 11 and an adsorption electrode 13 positioned inside the dielectric substrate 11. The electrostatic chuck member 2 adsorbs the wafer W using the placement surface 2s provided in the dielectric substrate 11.

In the following description, in each of the portions of the electrostatic chuck device 1, a side on which the wafer W is mounted on the electrostatic chuck member 2 is described as an upper side, and a base 3 side is described as a lower side. In addition, in the electrostatic chuck member 2, an up-down direction (Z-axis direction) is described as a thickness direction. That is, in the electrostatic chuck member 2 and the dielectric substrate 11, a direction orthogonal to the placement surface is described as the thickness direction.

The up-down direction described herein is merely a direction used for simplifying the description, and does not limit a position when the electrostatic chuck device 1 is used.

The dielectric substrate 11 has a circular plate shape in a plan view. The dielectric substrate 11 has the placement surface 2s on which the wafer W is mounted. In the placement surface 2s, for example, a plurality of protrusion portions (not illustrated) may be formed at predetermined intervals. The placement surface 2s supports the wafer W at tip portions of the plurality of protrusion portions.

The dielectric substrate 11 includes a first supporting plate 11a, a second supporting plate 11b, a third supporting plate 11c, and a joining layer 11d. The first supporting plate 11a, the second supporting plate 11b, the third supporting plate 11c have a plate shape extending along the placement surface 2s. The first supporting plate 11a, the second supporting plate 11b, and the third supporting plate 11c are stacked in this order from the lower side toward the upper side in the thickness direction. In addition, the joining layer 11d is disposed between the first supporting plate 11a and the second supporting plate 11b. The first supporting plate 11a and the second supporting plate 11b are joined to each other through the joining layer 11d. The joining layer 11d may also be provided between the second supporting plate 11b and the third supporting plate 11c. Further, the dielectric substrate 11 does not need to include the joining layer 11d. In this case, the first supporting plate 11a and the second supporting plate 11b are directly joined to each other.

The first supporting plate 11a, the second supporting plate 11b, the third supporting plate 11c, and the joining layer 11d forming the dielectric substrate 11 are formed of a composite sintered body having a sufficient mechanical strength and durability against corrosive gas and plasma thereof. As a dielectric material forming the dielectric substrate 11, a ceramic having a mechanical strength and durability against corrosive gas and plasma thereof is suitably used. As the ceramic forming the dielectric substrate 11, for example, an aluminum oxide (Al₂O₃) sintered body, an aluminum nitride (AlN) sintered body, or an aluminum oxide (Al₂O₃)-silicon carbide (Sic) composite sintered body is suitably used. In particular, from the viewpoints of dielectric characteristics, high corrosion resistance, plasma resistance, and heat resistance at a high temperature, the material forming the dielectric substrate 11 is preferably an aluminum oxide (Al₂O₃)-silicon carbide (SiC) composite sintered body.

In the present embodiment, a configuration of a compound material in the material forming the joining layer 11d may be different from a configuration of a compound material forming the first supporting plate 11a and the second supporting plate 11b. As described below, it is preferable that a thermal conductivity of the material forming the joining layer 11d is higher than thermal conductivities of the first supporting plate 11a and the second supporting plate 11b. For example, when the first supporting plate 11a, the second supporting plate 11b, and the joining layer 11d are formed of the same material (for example, an aluminum oxide-silicon carbide composite sintered body), the thermal conductivity of the joining layer 11d can be increased by increasing a ratio of a conductive material (for example, silicon carbide) in the joining layer 11d to be higher than a ratio of a conductive material in the first supporting plate 11a and the second supporting plate 11b.

An average primary particle diameter of an insulating material (for example, aluminum oxide) forming the first supporting plate 11a, the second supporting plate 11b, the third supporting plate 11c, and the joining layer 11d of the dielectric substrate 11 is preferably 0.5 μm or more and 10.0 μm or less, and more preferably 0.5 μm or more and 6.0 μm or less. The average primary particle diameter of the insulating material may be 1.0 μm or more and 8.0 μm or less, 2.0 μm or more and 7.0 μm or less, 2.5 μm or more and 5.0 μm or less, 2.8 μm or more and 4.0 μm or less, or the like. When the average primary particle diameter of the insulating material is 0.5 μm or more, the dielectric substrate 11 that is dense, has high voltage endurance, and has high durability can be obtained. In addition, by setting the average primary particle diameter of the insulating material to 10.0 μm or less, a heat exchange efficiency of the dielectric substrate 11 with heat transfer gas G in a gas flow path 60 described below can be sufficiently ensured.

A method for measuring the average primary particle diameter of the insulating material forming the dielectric substrate 11 is as follows. Using a field emission scanning electron microscope (FE-SEM) manufactured by JEOL Ltd., a cut surface of the dielectric substrate 11 in the thickness direction is observed, and the average of particle diameters of 200 particles of the insulating material is obtained as the average primary particle diameter using an intercept method.

A first gas hole 67, a second gas hole 68, and the gas flow path 60 are provided in the dielectric substrate 11.

The gas flow path 60 is provided between the first supporting plate 11a and the second supporting plate 11b. That is, the gas flow path 60 is provided inside the dielectric substrate 11. In the present embodiment, since the gas flow path 60 is provided between the first supporting plate 11a and the second supporting plate 11b, the gas flow path 60 can be easily formed by stacking the first supporting plate 11a and the second supporting plate 11b. A shape of the gas flow path 60 in a plan view can be freely selected as necessary as long as it extends along a planar direction of the placement surface. The number of gas flow paths 60 can be freely selected and for example, may be 1 to 10, 2 to 8, 3 to 6, or 4 to 5. However, the number of gas flow paths is not limited to this example.

In addition, the dielectric substrate 11 according to the present embodiment is configured by stacking a plurality of supporting plates in the thickness direction, and is disposed between supporting plates different from those of the adsorption electrodes 13 and the gas flow path 60. However, the adsorption electrode 13 and the gas flow path 60 may be disposed between the same supporting plates. That is, the adsorption electrode 13 and the gas flow path 60 may be disposed between the first supporting plate 11a and the second supporting plate 11b.

The gas flow path 60 extends along the planar direction of the placement surface 2s. The first gas hole 67 extends downward from the gas flow path 60. On the other hand, the second gas hole 68 extends upward from the gas flow path 60 and is opened to the placement surface 2s. The first gas hole 67 and the second gas hole 68 communicate with each other through the gas flow path 60. The heat transfer gas G flows through the first gas hole 67, the gas flow path 60, and the second gas hole 68.

The heat transfer gas G is, for example, a cooling gas such as He. The heat transfer gas G passes through the first gas hole 67 and flows into the gas flow path 60. The heat transfer gas G that passes through the gas flow path 60 cools the electrostatic chuck member 2. Further, the heat transfer gas G of the gas flow path 60 is supplied to the placement surface 2s from the second gas hole 68 to cool the wafer W mounted on the placement surface 2s.

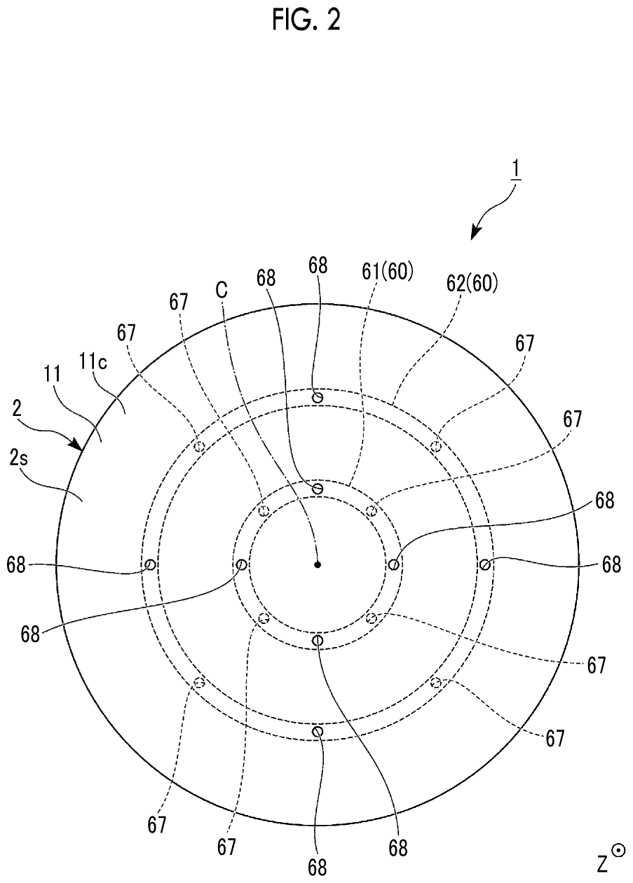

FIG. 2 is a schematic plan view illustrating an example of the electrostatic chuck member 2.

The gas flow path 60 according to the present embodiment extends annularly about the central axis C of the electrostatic chuck member 2. That is, the gas flow path 60 extends in an arc shape with respect to a center of the dielectric substrate 11. Two gas flow paths 60 are provided in the dielectric substrate 11 according to the present embodiment. Each of the plurality of gas flow paths 60 include an inner peripheral flow path 61 and an outer peripheral flow path 62 that are concentrically disposed. The inner peripheral flow path 61 extends in an arc shape with respect to the center of the dielectric substrate. The outer peripheral flow path 62 is disposed outside the inner peripheral flow path 61 in a concentric shape and extends in an arc shape.

The plurality of first gas holes 67 are disposed at regular intervals along the peripheral direction. Similarly, the plurality of second gas holes 68 are disposed at regular intervals along the peripheral direction. The first gas hole 67 and the second gas hole 68 are alternately disposed in the peripheral direction in a path of one gas flow path 60.

As illustrated in FIG. 1, a cross-section of the gas flow path 60 according to the present embodiment has a trapezoidal shape or a substantially trapezoidal shape. An inner surface of the gas flow path 60 includes a bottom surface portion 60a, a top surface portion 60b, and a pair of side surface portions 60c and 60d.

The bottom surface portion 60a and the top surface portion 60b are flat surfaces extending substantially in parallel to the placement surface 2s. The bottom surface portion 60a faces the same direction (upper side) as the placement surface 2s. The top surface portion 60b faces a direction (lower side) opposite to the placement surface 2s. The top surface portion 60b faces the bottom surface portion 60a. The bottom surface portion 60a is provided on the first supporting plate 11a. The top surface portion 60b is provided on the second supporting plate 11b. As described above, in a cross section passing through the central axis C, the top surface portion 60b, the bottom surface portion 60a, and the side surface portions 60c and 60d form the trapezoidal shape or the substantially trapezoidal shape. A side formed by the bottom surface portion 60a is longer than a side formed by the top surface portion 60b, and a side formed by the side surface portion 60d is longer than a side formed by the side surface portion 60c.

The pair of side surface portions 60c and 60d connect the bottom surface portion 60a and the top surface portion 60b to each other. The side surface portions 60c and 60d are provided over the second supporting plate 11b and the joining layer 11d. That is, at least a part of the side surface portions 60c and 60d is provided on the joining layer 11d.

A height dimension (a dimension along the thickness direction and a distance dimension between the bottom surface portion 60a and the top surface portion 60b) of the gas flow path 60 is preferably 30 μm or more and 500 μm or less. The height dimension may be 60 μm or more and 400 μm or less, 100 μm or more and 250 μm or less, or the like. In addition, a width dimension of the gas flow path 60 is preferably 500 μm or more and 3000 μm or less. The width direction may be 800 μm or more and 2500 μm or less, 1000 μm or more and 2000 μm or less, or the like. By setting the height dimension and the width dimension of the gas flow path 60 to be in the above-described ranges, a decrease in the strength of the dielectric substrate 11 can be suppressed while sufficiently ensuring a flow path cross-sectional area of the gas flow path 60.

Among the pair of side surface portions 60c and 60d, one side surface portion is an inner peripheral side surface portion 60c disposed on an arc inner peripheral side of the gas flow path 60, and the other side surface portion is an outer peripheral side surface portion 60d disposed on an arc outer peripheral side. Accordingly, the inner peripheral side surface portion 60c faces a radially outside of the central axis C, and the outer peripheral side surface portion 60d faces a radially inside of the central axis C. The inner peripheral side surface portion 60c and the outer peripheral side surface portion 60d are conical surfaces around the central axis C of the electrostatic chuck member 2.

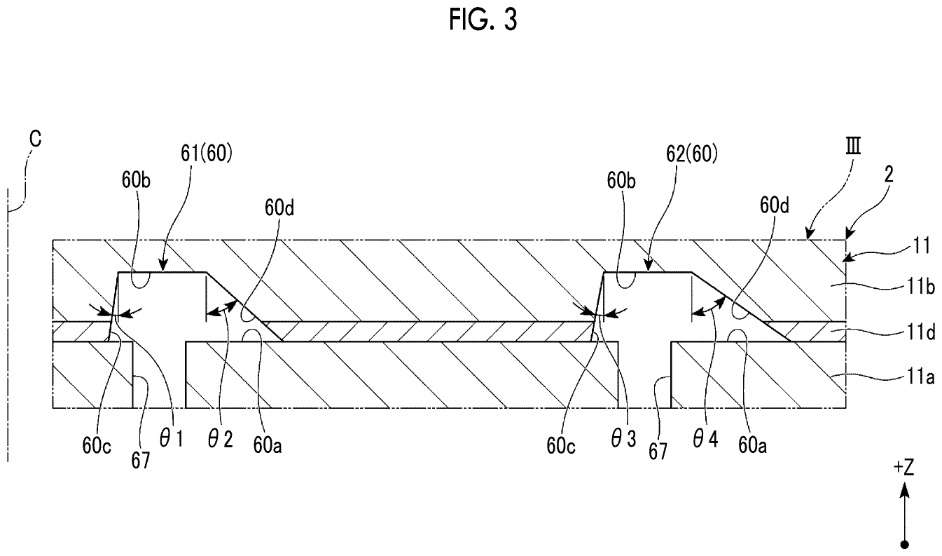

FIG. 3 is an enlarged view illustrating a region III of FIG. 1.

At least one of the pair of side surface portions 60c and 60d is inclined with respect to the thickness direction (Z-axis direction). In the present embodiment, both of the pair of side surface portions 60c and 60d are inclined with respect to the thickness direction. In the present embodiment, the inner peripheral side surface portion 60c of the inner peripheral flow path 61 is inclined at an inclination angle θ1 with respect to the thickness direction, and the outer peripheral side surface portion 60d is inclined at an inclination angle θ2 with respect to the thickness direction. Similarly, the inner peripheral side surface portion 60c of the outer peripheral flow path 62 is inclined at an inclination angle θ3 with respect to the thickness direction, and the outer peripheral side surface portion 60d is inclined at an inclination angle θ4 with respect to the thickness direction. In the flow path, each of the inclination angle θ1, the inclination angle θ2, the inclination angle θ3, and the inclination angle 64 may be maintained at a fixed angle or at a substantially fixed angle. In each of the gas flow paths, the height dimension may be maintained at a fixed value or a substantially fixed value. In addition, in each of the gas flow paths, a cross-sectional shape may be maintained in a fixed shape or a substantially fixed shape.

By inclining the inner peripheral side surface portion 60c with respect to the thickness direction, the height dimension of the gas flow path 60 gradually decreases from a start point of the inclination toward the radially inside of the electrostatic chuck member 2. Therefore, the cooling effect of the heat transfer gas G flowing through the gas flow path 60 is gradually weakened from the center of the gas flow path 60 toward the radially inside of the electrostatic chuck member 2. Similarly, by inclining the outer peripheral side surface portion 60d with respect to the thickness direction, the height dimension of the gas flow path 60 gradually decreases from a start point of the inclination toward the radially outside of the electrostatic chuck member 2. Therefore, the cooling effect of the heat transfer gas G flowing through the gas flow path 60 is gradually weakened from the center of the gas flow path 60 toward the radially outside of the electrostatic chuck member 2. In the present embodiment, the cooling efficiency by the heat transfer gas G can be gradually weakened at a boundary between a region where the gas flow path 60 is provided and a region where the gas flow path 60 is not provided. Therefore, a steep temperature gradient is not likely to be generated at the boundary between the region where the gas flow path 60 is provided and the region where the gas flow path 60 is not provided. As a result, non-uniformity in the temperature distribution of the wafer W mounted on the placement surface 2s can be suppressed.

In the present embodiment, the gas flow path 60 extends in an arc shape in a plan view. Therefore, when the wafer W has a disk shape, the wafer W can be cooled in an annular shape around the central axis C of the wafer W on the placement surface 2s on which the wafer W is mounted, and the temperature distribution of the wafer W is likely to be uniform.

In one gas flow path 60 of the present embodiment, it is preferable that the inclination angles θ2 and θ4 of the outer peripheral side surface portion 60d are larger than the inclination angles θ1 and θ3 of the inner peripheral side surface portion 60c (θ1<θ2, θ3<θ4). That is, in the present invention, when two or more gas flow paths are concentrically arranged, in at least one of the gas flow paths, an inclination angle of an outer peripheral side surface portion (outer side surface portion) is preferably larger than an inclination angle of an inner peripheral side surface portion (inner side surface portion). In addition, when two or more gas flow paths are concentrically arranged, an inclination angle of an inner peripheral side surface portion of one gas flow path positioned on the outer peripheral side is preferably larger than or equal to an inclination angle of an inner peripheral side surface portion of the other gas flow path(s) positioned on the inner peripheral side further than the gas flow path. An inclination angle of an outer peripheral side surface portion of one gas flow path positioned on the outer peripheral side is preferably larger than or equal to an inclination angle of an outer peripheral side surface portion of the other gas flow path(s) positioned on the inner peripheral side further than the gas flow path.

In a general processing step of the wafer W, the temperature of the wafer W is likely to increase radially outward with respect to the central axis C. Therefore, the temperature gradient of the radially outside of the central axis C with respect to the gas flow path 60 is likely to be larger than the temperature gradient of the radially inside. In the present embodiment, in the outer peripheral side surface portion 60d in which the temperature gradient is likely to be large, the non-uniformity of the temperature distribution generated by the wafer W can be further reduced by increasing the inclination angle to make the temperature gradient more gentle.

In the present embodiment, the inclination angle θ4 of the outer peripheral side surface portion 60d of the outer peripheral flow path 62 is preferably larger than or equal to the inclination angle θ2 of the outer peripheral side surface portion 60d of the inner peripheral flow path 61 (θ2≤θ4). In the present embodiment, in the radially outside region in which the temperature of the wafer W is likely to be high, the non-uniformity of the temperature distribution generated by the wafer W can be further reduced by making the temperature gradient of the placement surface 2s more gentle.

Similarly, in the present embodiment, the inclination angle θ3 of the inner peripheral side surface portion 60c of the outer peripheral flow path 62 is larger than or equal to the inclination angle θ1 of the inner peripheral side surface portion 60c of the inner peripheral flow path 61 (θ1≤θ3). In the present embodiment, in the radially outside region in which the temperature of the wafer W is likely to be high, the non-uniformity of the temperature distribution generated by the wafer W can be further reduced by making the temperature gradient of the placement surface 2s more gentle.

As described above, it is preferable that the inclination angles 61, 62, 03, and θ4 of the side surface portions 60c and 60d of the gas flow path 60 according to the present embodiment satisfy the following relationships.

01≤03, 02≤04, 01<02, and 03<04.

In addition, the inclination angles θ1 and θ3 of the inner peripheral side surface portions 60c of the inner peripheral flow path 61 and the outer peripheral flow path 62 are preferably 0° or more and 20° or less, more preferably 00 or more and 15° or less, and still more preferably 0° or more and 10° or less. The inclination angles θ1 and θ3 may be 1° or more and 8° or less, 2° or more and 7° or less, 3° or more and 6° or less, or the like. Further, the inclination angles θ2 and 94 of the outer peripheral side surface portion 60d of the inner peripheral flow path 61 and the outer peripheral flow path 62 are preferably 3° or more and 70° or less, more preferably 5° or more and 60° or less, and still more preferably 5° or more and 50° or less. The inclination angles θ2 and θ4 may be 4° or more and 40° or less, 8° or more and 30° or less, 10° or more and 20° or less, or the like. Since the inclination angles θ1, 02, 03, and θ4 satisfy the above-described ranges, the effect of suppressing the non-uniformity in the temperature distribution due to the inclination of the side surface portions 60c and 60d can be sufficiently obtained, and a significant decrease in the strength of the electrostatic chuck member 2 can be further suppressed.

In the present embodiment, the dielectric substrate 11 includes the first supporting plate 11a and the second supporting plate 11b stacked in the thickness direction. The gas flow path 60 is provided between the first supporting plate 11a and the second supporting plate 11b. Therefore, the complicated gas flow path 60 can be easily formed as compared to, for example, a case where the gas flow path 60 is formed by post-processing.

In the present embodiment, it is preferable that a thermal conductivity of the material forming the joining layer 11d is higher than thermal conductivities of the first supporting plate 11a and the second supporting plate 11b. As described above, the joining layer 11d is exposed to the gas flow path 60. That is, the heat transfer gas G passing through the gas flow path 60 can efficiently transfer the heat of the electrostatic chuck member 2 to the heat transfer gas G in the joining layer 11d.

As illustrated in FIG. 1, the adsorption electrode 13 is embedded in the dielectric substrate 11. The adsorption electrode 13 extends in a plate shape along the placement surface 2s of the dielectric substrate 11. By applying a voltage, the adsorption electrode 13 generates an electrostatic adsorption force to hold the wafer W in the placement surface 2s of the dielectric substrate 11.

The adsorption electrode 13 is formed of a composite of an insulating material and a conductive material. The insulating material in the adsorption electrode 13 is not particularly limited, and is preferably, for example, at least one selected from the group consisting of aluminum oxide (Al₂O₃), aluminum nitride (AN), silicon nitride (Si₃NA), yttrium (III) oxide (Y₂O₃), yttrium-aluminum-garnet (YAG), and SmAlO₃. The conductive material in the adsorption electrode 13 is preferably at least one selected from the group consisting of molybdenum carbide (Mo₂C), molybdenum (Mo), tungsten carbide (WC), tungsten (W), tantalum carbide (TaC), tantalum (Ta), silicon carbide (SiC), carbon black, carbon nanotubes, and carbon nanofibers.

The feeding terminal 16 for applying a direct current voltage to the adsorption electrode 13 is connected to the adsorption electrode 13. The feeding terminal 16 extends from the adsorption electrode 13 toward the lower side. The feeding terminal 16 is inserted into a through-hole 17 for a terminal that penetrates a part of the base 3 and the dielectric substrate 11 in the thickness direction. On an outer peripheral side of the feeding terminal 16, an insulator 23 for a terminal having insulating properties is provided. That is, the feeding terminal 16 is inserted into an insertion hole 15 of the insulator 23 for a terminal. The insulator 23 for a terminal insulates the base 3 formed of a metal and the feeding terminal 16.

The feeding terminal 16 is connected to an external power supply 21. The power supply 21 applies a voltage to the adsorption electrode 13. The number, shape, and the like of the feeding terminals 16 are determined depending on the form of the adsorption electrode 13, that is, whether the adsorption electrode 13 is unipolar or bipolar.

The base 3 supports the electrostatic chuck member 2 from the lower side. The base 3 is a metal member having a disk shape in a plan view. A material forming the base 3 is not particularly limited as long as it is a metal having excellent thermal conductivity, electrical conductivity, and workability or a compound material including the metal. As the material for forming the base 3, for example, an alloy of aluminum (Al), copper (Cu), stainless steel (SUS), titanium (Ti), or the like is suitably used. The material forming the base 3 is preferably an aluminum alloy from the viewpoints of thermal conductivity, electrical conductivity, and workability. It is preferable that at least a surface of the base 3 that is exposed to a plasma undergoes an alumite treatment or is coated with a resin such as a polyimide resin. In addition, it is more preferable that the entire surface of the base 3 undergoes an alumite treatment or is coated with a resin. The base 3 undergoes an alumite treatment or is coated with a resin such that plasma resistance of the base 3 is improved and abnormal discharge is prevented. Accordingly, the plasma stability of the base 3 can be improved, and surface scratches of the base 3 can also be prevented.

The body of the base 3 has a function as an internal electrode for generating a plasma. The body of the base 3 is connected to an external high-frequency power supply 22 through a matching box (not illustrated).

The base 3 is fixed to the electrostatic chuck member 2 through an adhesive. That is, an adhesive layer 55 that bonds the electrostatic chuck member 2 and the base 3 to each other is provided between the electrostatic chuck member 2 and the base 3. A heater for heating the electrostatic chuck member 2 may be embedded in the adhesive layer 55.

In the base 3 and the adhesive layer 55, a plurality of gas introduction holes 30 that vertically penetrate these components are provided. The gas introduction hole 30 is opened to the placement surface 2s. The gas introduction hole 30 is connected to a gas supply device (not illustrated). The gas introduction hole 30 is connected to the first gas hole 67 of the electrostatic chuck member 2. The gas introduction hole 30 supplies the heat transfer gas G to the first gas hole 67. The gas introduction hole 30 is surrounded by a cylindrical insulator 24. An outer peripheral surface of the insulator 24 is fixed to the base 3 through, for example, an adhesive.

Next, a preferable example of a method for manufacturing the electrostatic chuck member 2 according to the present embodiment will be described. The method for manufacturing the electrostatic chuck member 2 according to the present embodiment includes a supporting plate preparation step, a first joining step, a second joining step, a gas hole forming step, and a terminal connection step.

The supporting plate preparation step is a step of preparing the first supporting plate 11a, the second supporting plate 11b, and the third supporting plate 11c. In the following description, it is assumed that a material forming the first supporting plate 11a, the second supporting plate 11b, and the third supporting plate 11c are an aluminum oxide-silicon carbide (Al₂O₃—SiC) composite sintered body.

In the supporting plate preparation step, mixed powder including silicon carbide powder and aluminum oxide powder is formed into a desired shape, and subsequently is calcinated under freely selected conditions, for example, a temperature of 1600° C. to 2000° C. in a non-oxidative atmosphere, preferably, an inert atmosphere for a predetermined time. As a result, the first supporting plate 11a, the second supporting plate 11b, and the third supporting plate 11c can be obtained.

The first joining step is a step of joining the first supporting plate 11a and the second supporting plate 11b to each other and forming the gas flow path 60 between the supporting plates. As a preliminary step of the first joining step, surfaces of the first supporting plate 11a and the second supporting plate 11b that are joined to each other are polished. A gas flow path forming step includes a recessed groove forming step, an application step, and a joining step. That is, the method for manufacturing the electrostatic chuck member 2 includes a recessed groove forming step, an application step, and a joining step.

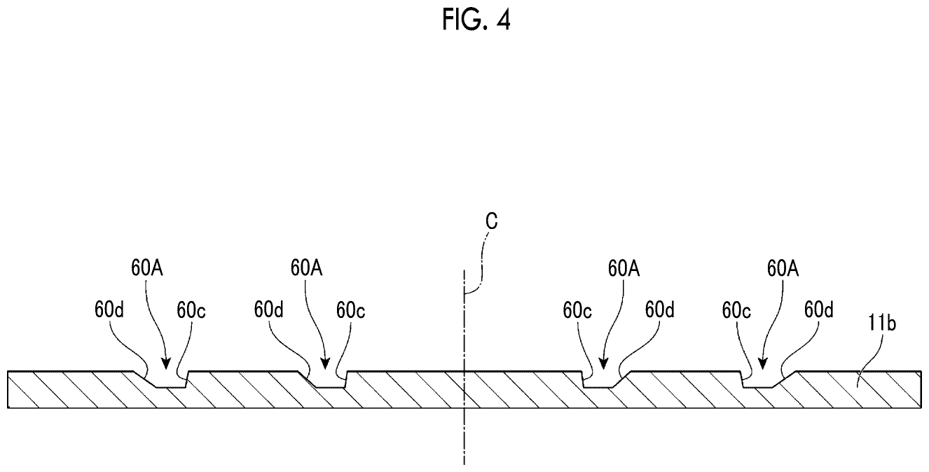

As illustrated in FIG. 4, in the recessed groove forming step, a recessed groove 60A is formed in the second supporting plate 11b. The side surface portions 60c and 60d of the recessed groove 60A are inclined with respect to the thickness direction of the second supporting plate 11b. That is, the width dimension of the recessed groove 60A increases toward the opening side. The recessed groove 60A includes two side surfaces having different inclinations and one bottom surface (flat surface) connecting the side surfaces. The recessed groove 60A may have an annular shape in a plan view.

In the present embodiment, a width dimension of the recessed groove 60A formed in the recessed groove forming step increases toward the opening side. Therefore, the gas flow path 60 having the side surface portions 60c and 60d that are inclined with respect to the thickness direction can be easily formed.

The recessed groove 60A can be formed by blasting or rotary processing. In particular, it is preferable that the recessed groove 60A is formed by rotary processing. In the rotary processing, while rotating the second supporting plate 11b to be processed around the central axis C, a tool is pressed against the processed surface to process the recessed groove 60A. In the rotary processing, for example, by gradually separating the tool from the processed surface during the processing of the recessed groove 60A, the inclined side surface portions 60c and 60d can be easily formed. In a specific example, during the processing of the recessed groove 60A, the bottom surface of the recessed groove is formed with the tool, and then the tool is gradually separated toward the outside and/or the inside from the processed surface to gradually change the processing depth. As a result, the side surface portions 60c and 60d can be formed. Alternatively, a desired recessed groove can be formed by combining a step of gradually changing the processing depth from the inside toward the outside and/or from the outside toward the inside and/or a step of maintaining a fixed depth.

In the present embodiment, the case where the recessed groove 60A is formed only in the second supporting plate 11b is described. However, the recessed groove 60A may be formed in only the first supporting plate 11a, or may be formed in each of the first supporting plate 11a and the second supporting plate 11b. That is, the recessed groove forming step may be a step of providing the recessed groove 60A in at least one of the first supporting plate 11a or the second supporting plate 11b. When the recessed groove 60A is formed in each of the first supporting plate 11a and the second supporting plate 11b, the recessed grooves 60A of the first supporting plate 11a and the second supporting plate 11b overlap each other when seen from the thickness direction. When this configuration is adopted, the dimension of the gas flow path 60 to be formed in the thickness direction is likely to increase.

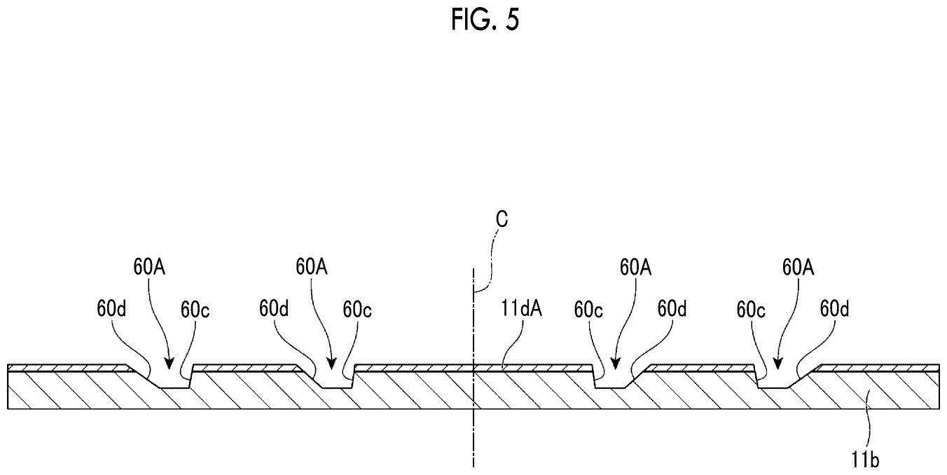

In the application step illustrated in FIG. 5, first, a joining layer paste 11dA including a powder material having the same composition as or the same main component as the first supporting plate 11a and the second supporting plate 11b is prepared. Next, in the second supporting plate 11b obtained in the recessed groove forming step, the joining layer paste 11dA is applied to a portion other than the recessed groove 60A on the surface where the recessed groove 60A is formed. That is, it is preferable that the recessed groove 60A is not filled with the joining layer paste 11dA, and it is preferable that the joining layer paste 11dA does not penetrate into the recessed groove 60A. In the present embodiment, the case where the joining layer paste 11dA is applied to the second supporting plate 11b is described. However, the joining layer paste 11dA may be applied to the first supporting plate 11a. The joining layer paste 11dA may be applied to at least one of the first supporting plate 11a or the second supporting plate 11b.

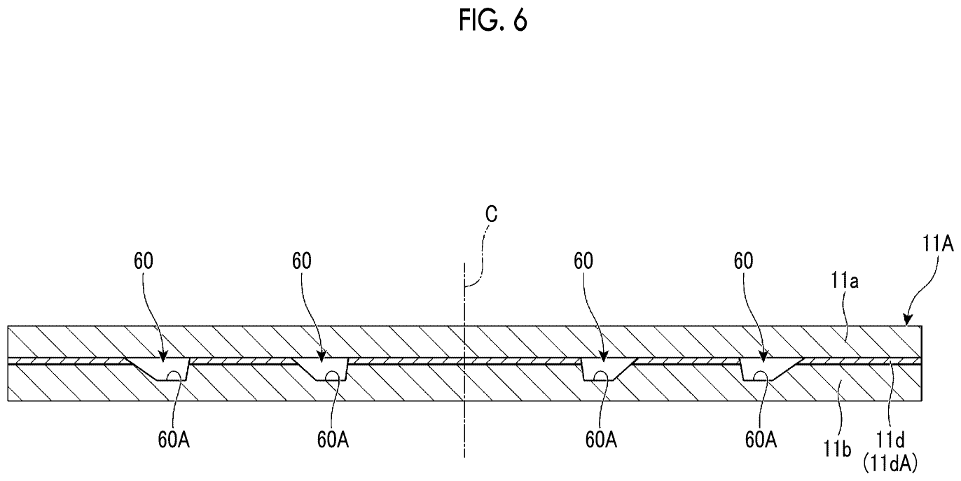

In the joining step illustrated in FIG. 6, the first supporting plate 11a and the second supporting plate 11b obtained in the application step are stacked in the thickness direction through the joining layer paste 11dA and are hot-pressed, for example, under a high temperature and a high pressure to integrate the first supporting plate 11a and the second supporting plate 11b. The atmosphere during the hot-press can be freely selected, but a vacuum or an inert atmosphere such as Ar, He, or N₂ is preferable. In addition, the pressure is preferably 1 MPa to 50 MPa and more preferably 5 MPa to 20 MPa. The temperature is preferably 1600° C. to 1900° C. and more preferably 1650° C. to 1850° C. The joining layer paste 11dA is calcinated and solidified by the hot-press of the joining step to form the joining layer 11d, and the first supporting plate 11a and the second supporting plate 11b are joined and integrated through the joining layer 11d. In the following description, the joined body of the first supporting plate 11a and the second supporting plate 11b that are joined and integrated to each other by the first joining step is referred to as a joined supporting plate 11A.

In the present embodiment, the first supporting plate 11a and the second supporting plate 11b are joined to each other through the joining layer 11d. However, the first supporting plate 11a and the second supporting plate 11b may be directly joined to each other. In this case, it is preferable that the above-described joining step is performed after polishing the surfaces of the first supporting plate 11a and the second supporting plate 11b facing each other.

The second joining step is a step of joining the third supporting plate 11c and the joined supporting plate 11A to each other and forming the adsorption electrodes 13 between the supporting plates. In the second joining step, first, a paste of a conductive material such as a conductive ceramic is applied to one surface of any one of the third supporting plate 11c or the joined supporting plate 11A, and the joining layer paste is applied to a region other than a region where a coating film of the conductive material is formed. Next, the third supporting plate 11c and the joined supporting plate 11A are stacked with the surface to which the paste is applied interposed therebetween, and is hot-pressed and integrated, for example, at a high temperature and a high pressure. With this hot-press, the paste of the conductive material is calcinated to form the adsorption electrode 13, and the third supporting plate 11c and the joined supporting plate 11A are joined and integrated.

The gas hole forming step is a step of forming the first gas hole 67 and the second gas hole 68 in the joined body where the first supporting plate 11a, the second supporting plate 11b, and the third supporting plate 11c are joined to open the gas flow path 60 to the outside. After performing the gas hole forming step, a cleaning step is performed. In the cleaning step, water or a cleaning liquid is allowed to flow into the first gas hole 67 or the second gas hole 68 to clean away particles in the gas flow path 60.

The terminal connection step is a step of providing a through-hole in the joined body in which the first supporting plate 11a, the second supporting plate 11b, and the third supporting plate 11c are joined to each other, disposing the feeding terminal 16 in the through-hole, and joining the feeding terminal and the adsorption electrode 13 to each other.

The electrostatic chuck member 2 is manufactured through the above-described steps. In addition, the manufactured electrostatic chuck member 2 is mounted on the base 3 where the insulator 23 for a terminal and the insulator 24 for a flow path of the heat transfer gas G are provided to configure the electrostatic chuck device 1.

### Modification Example

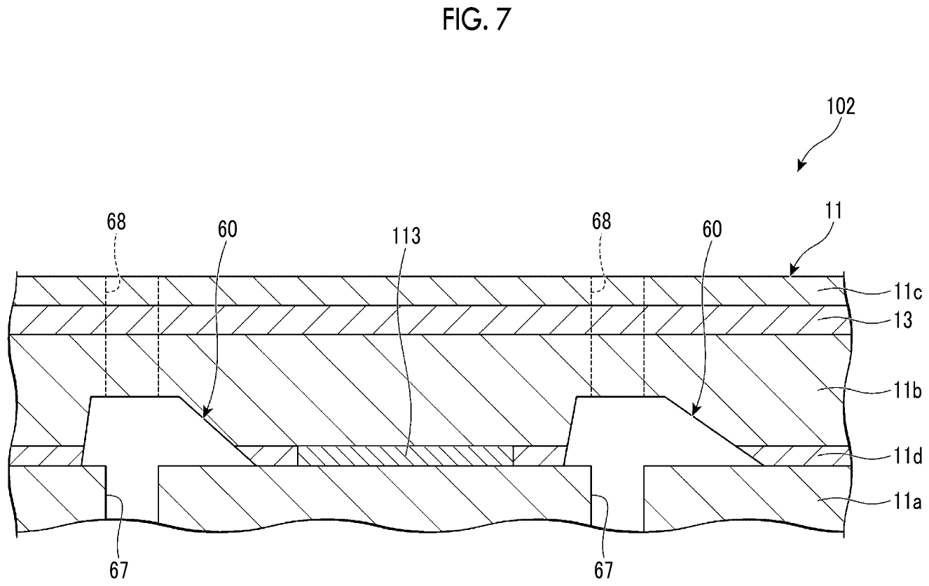

FIG. 7 is a partial schematic cross-sectional view illustrating an electrostatic chuck member 102 according to a modification example.

As in the above-described embodiment, the electrostatic chuck member 102 includes the dielectric substrate 11 and the adsorption electrode 13 that is embedded in the dielectric substrate 11. In addition, the gas flow path 60 is provided inside the dielectric substrate 11.

The electrostatic chuck member 102 according to the present modification example further includes a sub-electrode layer 113 that is embedded in the dielectric substrate. The sub-electrode layer 113 according to the present modification example is disposed between the first supporting plate 11a and the second supporting plate 11b. That is, the sub-electrode layer 113 is disposed on the same plane as the gas flow path 60. That is, a bottom surface of the sub-electrode layer 113 and a bottom surface of the gas flow path 60 are at the same height position as viewed from the side surface. The sub-electrode layer 113 according to the present modification example is not exposed to the gas flow path 60, but the sub-electrode layer 113 may be exposed to the gas flow path 60.

A feeding terminal (not shown) is connected to the sub-electrode layer 113. The sub-electrode layer 113 functions as, for example, a heater electrode. In this case, the sub-electrode layer 113 as the heater electrode generates heat by causing a current to flow. Further, the sub-electrode layer 113 may function as a radio frequency (RF) electrode. In this case, the sub-electrode layer 113 as the RF electrode generates a plasma on the plate-shaped sample by applying a voltage.

The sub-electrode layer 113 according to the present modification example is disposed on the same plane as the gas flow path 60, and thus can be formed between the first supporting plate 11a and the second supporting plate 11b together with the gas flow path 60. Therefore, the high-function electrostatic chuck member 102 can be provided while suppressing the manufacturing method from being unnecessarily complicated.

Hereinabove, various embodiments of the present invention has been described. However, the configurations of the embodiments, a combination thereof, and the like are exemplary, and additions, omissions, replacements and other changes can be made for the configurations within a range not departing from the scope of the present invention. Further, the present invention is not limited to the embodiments.

### INDUSTRIAL APPLICABILITY

The present invention can provide an electrostatic chuck member where a temperature distribution of a wafer is likely to be uniform, an electrostatic chuck device, and a method for manufacturing an electrostatic chuck member.

### REFERENCE SIGNS LIST

1: Electrostatic chuck device
2, 102: electrostatic chuck member
2s: placement surface
3: base
11: dielectric substrate
11A: joined supporting plate
11a: first supporting plate
11b: second supporting plate
11c: third supporting plate
11d: joining layer
11dA: joining layer paste
13: adsorption electrode
15: insertion hole
16: feeding terminal
17: through-hole for terminal
21: external power supply
22: external high-frequency power supply
23: insulator for terminal
24: cylindrical insulator
30: gas introduction hole
32: through-hole
55: adhesive layer
60: gas flow path
60a: bottom surface portion
60b: top surface portion
60c: side surface portion
60c: inner peripheral side surface portion
60d: outer peripheral side surface portion
60A: recessed groove
61: inner peripheral flow path
62: outer peripheral flow path
67: first gas hole
68: second gas hole
113: sub-electrode layer
C: central axis
G: heat transfer gas
W: wafer (sample)
Z: Z-axis (Z direction)
III: region
θ1, θ2, θ3, θ4: inclination angle

1. An electrostatic chuck member comprising:
a dielectric substrate having a placement surface on which a sample is mounted, wherein a direction orthogonal to the placement surface is a thickness direction thereof; and
an adsorption electrode which is embedded in the dielectric substrate, wherein
a gas flow path, which extends along a planar direction of the placement surface, is provided in the dielectric substrate,
the gas flow path has an inner surface which includes
a bottom surface portion that faces the same direction as the placement surface,
a top surface portion that faces the bottom surface portion, and
a pair of side surface portions that connect the bottom surface portion and the top surface portion,
wherein at least one of the side surface portions is inclined with respect to the thickness direction.

2. The electrostatic chuck member according to claim 1,
wherein the gas flow path extends in an arc shape with respect to a center of the dielectric substrate.

3. The electrostatic chuck member according to claim 2,
wherein among the pair of side surface portions, one side surface portion is an inner peripheral side surface portion which is disposed on an arc inner peripheral side and the other side surface portion is an outer peripheral side surface portion which is disposed on an arc outer peripheral side, and
an inclination angle of the outer peripheral side surface portion is larger than an inclination angle of the inner peripheral side surface portion.

4. The electrostatic chuck member according to claim 1,
wherein a plurality of the gas flow paths includes
an inner peripheral flow path which extends in an arc shape with respect to a center of the dielectric substrate, and
an outer peripheral flow path which extends in an arc shape and is concentrically disposed outside of the inner peripheral flow path,
wherein
among the pair of side surface portions thereof, one side surface portion is an inner peripheral side surface portion which is disposed on an arc inner peripheral side and the other side surface portion is an outer peripheral side surface portion which is disposed on an arc outer peripheral side, and
an inclination angle of the outer peripheral side surface portion of the outer peripheral flow path is larger than an inclination angle of the outer peripheral side surface portion of the inner peripheral flow path.

5. The electrostatic chuck member according to claim 4,
wherein an inclination angle of the inner peripheral side surface portion of the outer peripheral flow path is larger than an inclination angle of the inner peripheral side surface portion of the inner peripheral flow path.

6. The electrostatic chuck member according to claim 1,
wherein the dielectric substrate includes a first supporting plate and a second supporting plate which are stacked in the thickness direction, and
the gas flow path is provided between the first supporting plate and the second supporting plate.

7. The electrostatic chuck member according to claim 6,
wherein the first supporting plate and the second supporting plate are joined to each other through a joining layer,
at least a part of the side surface portion is located in the joining layer, and
a thermal conductivity of the joining layer is higher than thermal conductivities of the first supporting plate and the second supporting plate.

8. The electrostatic chuck member according to claim 1, further comprising
a sub-electrode layer which is embedded in the dielectric substrate,
wherein the sub-electrode layer is disposed on the same plane as the gas flow path.

9. An electrostatic chuck device comprising:
the electrostatic chuck member according to claim 1; and
a base that supports the electrostatic chuck member from a side opposite to the placement surface.

10. A method for manufacturing an electrostatic chuck member which includes a dielectric substrate, which includes a first supporting plate and a second supporting plate, and an adsorption electrode embedded in the dielectric substrate, the method comprising:
a recessed groove forming step of forming a recessed groove on at least one of the first supporting plate and the second supporting plate; and
a joining step of stacking and joining the first supporting plate and the second supporting plate in a thickness direction thereof,
wherein in the recessed groove forming step, the recessed groove is formed wherein a width dimension thereof increases toward an opening side thereof.

11. The method for manufacturing an electrostatic chuck member according to claim 10,
wherein in the joining step, a surface of the supporting plate where the recessed groove has been formed is joined to a surface of the other supporting plate,
the recessed groove has an arc shape in a plan view,
the recessed groove includes an inner peripheral side surface portion which is disposed on an arc inner peripheral side, an outer peripheral side surface portion which is disposed on an arc outer peripheral side, and a bottom surface portion which connects the side surface portions, and
at least one of the side surface portions is inclined with respect to the thickness direction of the supporting plate.

12. The method for manufacturing an electrostatic chuck member according to claim 10,
wherein an inclination angle of the outer peripheral side surface portion is larger than an inclination angle of the inner peripheral side surface portion.

13. The method for manufacturing an electrostatic chuck member according to claim 10, further comprising:
an application step which is performed between the recessed groove forming step and the joining step, wherein a joining layer paste is applied to at least one of the surface of the supporting plate, where the recessed groove has been provided, and the surface of the other supporting plate, wherein
the first supporting plate and the second supporting plate are joined through the joining layer paste in the joining step.

14. The electrostatic chuck member according to claim 1,
wherein a cross-section of the gas flow path in a radical direction has a trapezoidal shape or a substantially trapezoidal shape.

15. The electrostatic chuck member according to claim 1,
wherein the bottom surface portion and the top surface portion of the gas flow path are parallel to each other, and
a dimension in a radical direction of the bottom surface portion is larger than that of the top surface portion in a plan view.

16. The electrostatic chuck member according to claim 1,
wherein the gas flow path extends in a ring shape in a plan view, and
a dimension in a radical direction of the bottom surface portion is larger than that of the top surface portion in a plan view.
